(19) United States
(12) Patent Application Publication
(10) Pub. No.: US 2026/0122762 A1
(43) Pub. Date: Apr. 30, 2026

(54) ELECTRONIC DEVICE AND METHOD FOR ASSEMBLING ELECTRONIC DEVICE

(71) Applicant: DENSO CORPORATION, Kariya-city (JP)

(72) Inventor: Toshihiro MIYAKE, Kariya-city (JP)

(21) Appl. No.: 19/361,744

(22) Filed: Oct. 17, 2025

(30) Foreign Application Priority Data
Oct. 25, 2024 (JP) 2024-188246

(51) Int. Cl. H05K 1/02; H05K 3/34; H05K 7/14; H05K 7/20

(52) U.S. Cl. CPC H05K 1/0203; H05K 3/341; H05K 7/1427; H05K 7/20409; H05K 7/20463; H05K 2201/10378; H05K 2201/10522

(57) ABSTRACT

An electronic device includes a housing, a substrate, a semiconductor, a heat sink fin, a protrusion, and a recess. The housing has an opening. The substrate is arranged in the housing. The semiconductor is mounted on the substrate and arranged in the housing. The heat sink fin is arranged above the semiconductor in the housing and has a part exposed to an outside of the housing from the opening. The protrusion is provided on either one of the heat sink fin or the housing. The recess is provided on another of the heat sink fin and the housing at a position corresponding to the protrusion. The protrusion is fitted to the recess such that a surface of the protrusion is spaced away from a surface of the recess.

### CROSS REFERENCE TO RELATED APPLICATION

The present application claims the benefit of priority from Japanese Patent Application No. 2024-188246 filed on October 25, 2024. The disclosures of the above application are incorporated herein.

### TECHNICAL FIELD

The present disclosure relates to an electronic device and a method for assembling an electronic device.

### BACKGROUND

Conventionally, an electronic component unit includes a substrate, a semiconductor package mounted on the front surface of the substrate, a heat sink having a retainer plate mounted on the semiconductor package, and a reinforcing plate positioned on the back surface of the substrate.

### SUMMARY

According to at least one embodiment of the present disclosure, an electronic device includes a housing, a substrate, a semiconductor, a heat sink fin, a protrusion, and a recess. The housing has an opening. The substrate is arranged in the housing. The semiconductor is mounted on the substrate and arranged in the housing. The heat sink fin is arranged above the semiconductor in the housing and has a part exposed to an outside of the housing from the opening. The protrusion is provided on either one of the heat sink fin or the housing. The recess is provided on another of the heat sink fin and the housing at a position corresponding to the protrusion. The protrusion is fitted to the recess such that a surface of the protrusion is spaced away from a surface of the recess.

### BRIEF DESCRIPTION OF DRAWINGS

The details of one or more embodiments are set forth in the accompanying drawings and the description below. Other features and advantages will be apparent from the description and drawings, and from the claims.

FIG. 1 is a view showing a vertical cross section of an electronic device according to a first embodiment and a second embodiment.

FIG. 2A is a schematic view showing a heat sink fin of the electronic device according to the first embodiment and the second embodiment.

FIG. 2B is a schematic view showing a housing according to the first embodiment and the second embodiment.

FIG. 3A is a schematic view illustrating a recess of the housing and a protrusion of the heat sink fin fitted to each other, according to the first embodiment and the second embodiment.

FIG. 3B is a schematic view illustrating a recess of the housing and a protrusion of the heat sink fin fitted to each other, according to the first embodiment and the second embodiment.

FIG. 3C is a schematic view illustrating a recess of the housing and a protrusion of the heat sink fin fitted to each other, according to the first embodiment and the second embodiment.

FIG. 3D is a schematic view illustrating a recess of the housing and a protrusion of the heat sink fin fitted to each other, according to the first embodiment and the second embodiment.

FIG. 4 is a schematic view illustrating a recess of the housing and a protrusion of the heat sink fin fitted to each other, according to another embodiment.

FIG. 5 is a schematic diagram illustrating an assembly process of the electronic device according to the first embodiment.

FIG. 6 is a schematic diagram illustrating an assembly process of the electronic device according to the second embodiment.

### DETAILED DESCRIPTION

According to a comparative example, an electronic component unit includes a substrate, a semiconductor package mounted on the front surface of the substrate, a heat sink having a retainer plate mounted on the semiconductor package, and a reinforcing plate positioned on the back surface of the substrate. In the above-described electronic component unit, corners of the reinforcing plate and corners of the retainer plate are fastened together with fasteners, thereby pressing and securing the semiconductor package to the heat sink.

Since the above-described electronic component unit is partially fastened at the corners with the fasteners, which causes the semiconductor package and the heat sink to be bent, resulting in an uneven distance between the semiconductor package and the heat sink. Furthermore, since electronic components cannot be mounted on the front surface of the substrate in areas where the fasteners securing the semiconductor package and the heat sink together with the substrate are in contact with the substrate, the electronic component may become large.

According to one aspect of the present disclosure, an electronic device is capable of efficiently releasing a heat generated from a semiconductor while being compact and lightweight.

An electronic device according to a first aspect of the present disclosure includes a housing, a substrate, a semiconductor, a heat sink fin, a protrusion, and a recess. The housing has an opening. The substrate is arranged in the housing. The semiconductor is mounted on the substrate and arranged in the housing. The heat sink fin is arranged above the semiconductor in the housing and has a part exposed to an outside of the housing from the opening. The protrusion is provided on either one of the heat sink fin or the housing. The recess is provided on another of the heat sink fin and the housing at a position corresponding to the protrusion. The protrusion is fitted to the recess such that a surface of the protrusion is spaced away from a surface of the recess.

According to the first aspect of the present disclosure, since the substrate including the semiconductor and the heat sink fin are positioned in the housing without a retainer member that presses the semiconductor to the heat sink fin, the substrate can be prevented from being bent and a distance between the semiconductor and the heat sink fin can be made to be uniform. The electronic device can become compact and lightweight by having no retainer member. Furthermore, the gap between the protrusion and the recess can absorb assembly tolerances between the heat sink fin and the semiconductor, and between the substrate and the housing, thereby maintaining a uniform distance between the semiconductor and the heat sink fin. Therefore, a heat generated from the semiconductor can be effectively dissipated, and the electronic device can become compact and lightweight.

In a method for assembling an electronic device, according to a second aspect of the present disclosure, a heat sink fin is attached to a semiconductor. The semiconductor, to which the heat sink fin is attached, is mounted on a substrate. The substrate, on which the semiconductor is mounted, is placed inside a housing by inserting the substrate into the housing. A part of the heat sink fin is exposed to an outside of the housing from an opening of the housing. A protrusion of the heat sink fin is fitted to a recess of the housing such that a surface of the protrusion is spaced apart from a surface of the recess, or a recess of the heat sink fin is fitted to a protrusion of the housing such that a surface of the recess is spaced apart from a surface of the protrusion.

According to the second aspect of the present disclosure, the electronic device can be assembled by attaching the heat sink fin to the semiconductor, mounting the semiconductor with the heat sink fin on the substrate, inserting the substrate into the housing, and fitting the first fitting portion to the second fitting portion.

In a method for assembling an electronic device, according to a third aspect of the present disclosure, a semiconductor is mounted on a substrate. A heat sink fin is attached to the semiconductor mounted on the substrate. The substrate, on which the semiconductor is mounted, is placed inside a housing by inserting the substrate into the housing. A part of the heat sink fin is exposed to an outside of the housing from an opening of the housing. A protrusion of the heat sink fin is fitted to the recess of the housing such that a surface of the protrusion is spaced apart from a surface of the recess, or a recess of the heat sink fin is fitted to a protrusion of the housing such that a surface of the recess is spaced apart from a surface of the protrusion.

According to the third aspect of the present disclosure, the electronic device can be assembled by mounting the semiconductor on the substrate, attaching the heat sink fin to the semiconductor, inserting the substrate into the housing, and fitting the first fitting portion to the second fitting portion.

The embodiments of the present disclosure will be described below with reference to the drawings. In the following embodiments, portions that are the same as or equivalent to those described in a preceding embodiment are denoted by the same reference numerals, and a description of the same or equivalent portions may be omitted. When only some of the configuration elements are described in the embodiment, the remaining configuration elements can be referred from those described in the preceding embodiment. The following embodiments may be partially combined with each other even if such a combination is not explicitly described as long as there is no disadvantage with respect to such a combination.

### First Embodiment

### 1-1. Configuration of an Electronic Device

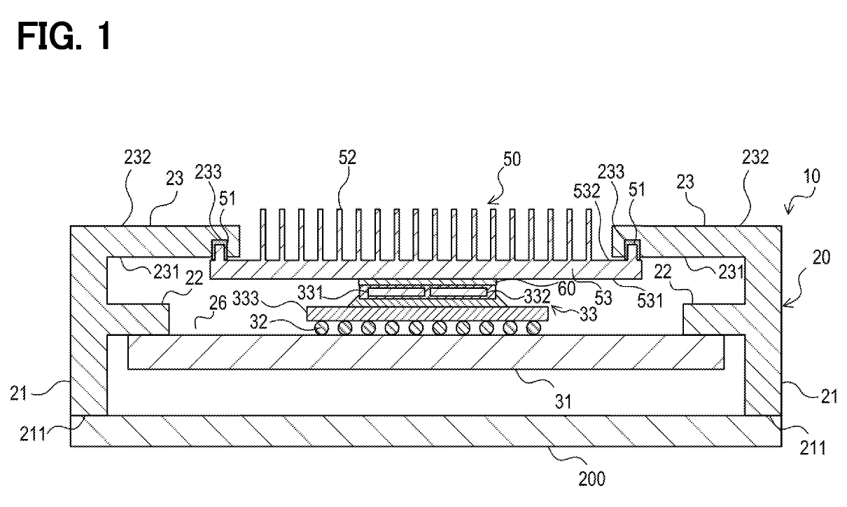

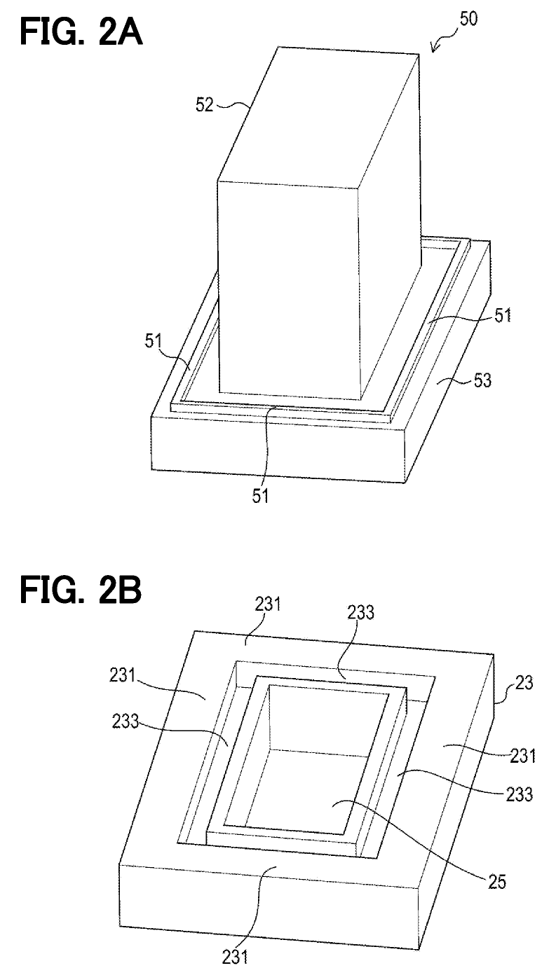

A configuration of an electronic device 10 according to the present embodiment will be described with references to FIGS. 1 and 2. The electronic device 10 includes a housing 20, a substrate 31, a semiconductor 33, a heat sink fin 50, a lid 200, a first fitting portion 51, a second fitting portion 233, an adhesive layer 60, and a sealing member 70.

The housing 20 is made of a metal material such as aluminum, an aluminum alloy, copper, or a copper alloy. The housing 20 includes a rectangular parallelepiped shape with an opening at a bottom. The housing 20 includes four side faces 21, an upper face 23, and a middle face 22. The upper face 23 includes an inner surface 231 facing inward of the housing 20 and an outer surface 232 facing outward of the housing 20. The upper face 23 includes an opening 25 that is quadrilateral. The middle face 22 is positioned approximately at the middle of the housing 20 in a vertical direction. The middle face 22 is parallel to the upper face 23 and is connected to the four side faces 21. The middle face 22 includes an opening 26 that is quadrilateral. The opening 26 is larger than the opening 25.

The lid 200 is a plate-shaped member formed of the same metal material as the housing 20. The lid 200 is attached to lower ends 211 of the four side faces 21. The substrate 31 is accommodated inside the housing 20. The substrate 31 is larger than the opening 26 and is attached to the middle face 22. In the present embodiment, the substrate 31 is fixed to the middle face 22 with a screw.

The semiconductor 33 includes an interposer 333 and multiple chips 331 and 332. The multiple chips 331 and 332 are mounted on the interposer 333. The interposer 333 includes, for example, a wiring electrically connecting the multiple chips 331 and 332, and a wiring electrically connecting each of the multiple chips 331 and 332 and the substrate 31. Multiple solder balls 32 are provided between the interposer 333 and the substrate 31. The multiple solder balls 32 are arranged in a grid pattern. The interposer 333 is electrically connected to the substrate 31 via the multiple solder balls 32.

The adhesive layer 60 is thinly and evenly deposited on an upper surface of the semiconductor 33, i.e., on an upper surface of the multiple chips 331 and 332. The adhesive layer 60 is made of, for example, a silicone resin or an epoxy resin. The adhesive layer 60 is adhered to the heat sink fin 50 described later. The adhesive layer 60 includes a thickness X1 and an elastic modulus Y1.

If the adhesive layer 60 is made of a silicone resin, a heat resistance of a heat dissipation path from the semiconductor 33 to the heat sink fin 50 can be improved. If the adhesive layer 60 is made of a silicone resin or an epoxy resin, which contains fillers having a high thermal conductivity, a heat dissipating performance of the heat dissipation path can be improved.

The heat sink fin 50 is made of, a metal material such as aluminum, an aluminum alloy, copper, and a copper alloy. In the present embodiment, the heat sink fin 50 is made of the same metal material as the housing 20. Therefore, under a thermal cycling condition, a thermal stress caused by a difference in thermal expansion coefficients between the housing 20 and the heat sink fin 50 can be reduced. The term "thermal cycling" is defined as a process in which the housing 20, the heat sink fin 50, the semiconductor 33, and the substrate 31 are heated and expand due to a heat generated from the semiconductor 33 (described later), and then release the heat to return to their original states.

The heat sink fin 50 includes a base 53 having a plate shape and multiple fins 52. The base 53 is larger than the opening 25. In other words, a planar area of the base 53 is larger than an area of the opening 25. The base 53 includes a first face 531 and a second face 532 facing away from the first face 531. In a case where the heat sink fin 50 is attached to the housing 20, the first face 531 faces the semiconductor 33 and the second face 532 faces outward of the housing 20. The multiple fins 52 are connected to the second face 532 in a direction perpendicular to the base 53. For example, the multiple fins 52 may be arranged at equal intervals.

The heat sink fin 50 is positioned above the semiconductor 33, i.e., upward of the multiple chips 331 and 332. Specifically, the heat sink fin 50 is positioned such that the first face 531 is in contact with the adhesive layer 60 that is positioned on the upper surface of the semiconductor 33. As a result, the first face 531 is bonded to the upper surface of the semiconductor 33 via the adhesive layer 60.

In another embodiment, the housing 20 may be made of a metal material different from the heat sink fin 50. In another embodiment, the electronic device 10 may not include the adhesive layer 60 between the semiconductor 33 and the heat sink fin 50. In this case, the heat sink fin 50 may be placed such that the first face 531 is in contact with the upper surface of the semiconductor 33.

The first fitting portion 51 is provided on the heat sink fin 50. Specifically, as shown in FIG. 2A, the first fitting portion 51 is provided on the second face 532 of the base 53, and positioned outside the multiple fins 52 so as to enclose the multiple fins 52. In FIG. 2A, shapes of the multiple fins 52 are simplified to be shown as one rectangular parallelepiped. In FIG. 2B, only a vicinity of the opening 25 of the housing 20 is illustrated, and the region outside thereof is omitted.

In the present embodiment, the first fitting portion 51 is formed as a protrusion protruding from the second face 532. Although the first fitting portion 51 protrudes in the same direction as a direction in which the multiple fins 52 protrude, an amount of protrusion of the first fitting portion 51 is smaller than an amount of protrusion of the multiple fins 52. In the present embodiment, the first fitting portion 51 corresponds to a first protrusion of the present disclosure.

In the present embodiment, the first fitting portion 51 is integrated with the heat sink fin 50. For example, the heat sink fin 50 and the first fitting portion 51 are integrally formed using a single mold. This structure can reduce the number of components of the electronic device 10.

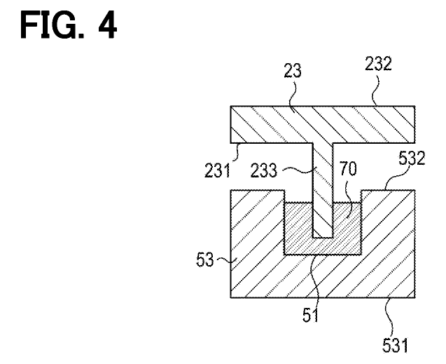

In another embodiment, as shown in FIG. 4, the first fitting portion 51 may be formed as a recess that recesses from the second face 532 toward the first face 531. In this case, the first fitting portion 51 corresponds to a first recess of the present disclosure. Furthermore, in another embodiment, the first fitting portion 51 may be formed separately from the heat sink fin 50 and attached to the second face 532 of the heat sink fin 50 by, for example, adhesive, brazing, or welding.

The second fitting portion 233 is provided at a position of the housing 20 corresponding to the first fitting portion 51 in a state where the heat sink fin 50 are bonded or placed on the semiconductor 33. Specifically, as shown in FIG. 2B, the second fitting portion 233 is provided on the inner surface 231 of the upper face 23, and positioned outside the opening 25 so as to enclose the opening 25.

In the present embodiment, the second fitting portion 233 is formed as a recess corresponding to the first fitting portion 51. A length of a protrusion of the first fitting portion 51 is larger than a depth of a recess of the second fitting portion 233. In the present embodiment, the second fitting portion 233 corresponds to a second recess of the present disclosure.

In the present embodiment, the second fitting portion 233 is formed integrally with the housing 20. For example, the housing 20 and the second fitting portion 233 are integrally formed using a single mold. This structure can reduce the number of components of the electronic device 10.

In another embodiment, as shown in FIG. 4, when the first fitting portion 51 is formed as a recess, the second fitting portion 233 may be formed as a protrusion protruding from the inner surface 231 inward of the housing 20. In this case, the second fitting portion 233 corresponds to a second protrusion of the present disclosure. Furthermore, in another embodiment, the second fitting portion 233 may be formed separately from the housing 20 and attached to the inner surface 231 of the housing 20 by, for example, adhesive, brazing, or welding.

In a state where the heat sink fin 50 are bonded or placed on the semiconductor 33, the first fitting portion 51 is fitted into the second fitting portion 233. In other words, the protrusion of the first fitting portion 51 is fitted to the recess of the second fitting portion 233. The first fitting portion 51 is fitted to the second fitting portion 233 in a state where a surface of the first fitting portion 51 is spaced apart from a surface of the second fitting portion 233. In other words, the first fitting portion 51 is fitted to the second fitting portion 233 in a state where a surface of the protrusion is spaced apart from a surface of the recess and a gap is created between the surface of the protrusion and the surface of the recess. Additionally, in a state where the second face 532 is spaced apart from the inner surface 231, the first fitting portion 51 is fitted to the second fitting portion 233. In other words, the heat sink fin 50 is assembled to the housing 20 in a state where the heat sink fin 50 is not in contact with the housing 20.

Additionally, in another embodiment, even if the first fitting portion 51 is formed as the recess and the second fitting portion 233 is formed as the protrusion, the first fitting portion 51 is fitted to the second fitting portion 233 in a state where the surface of the recess is spaced apart from the surface of the protrusion.

When the heat sink fin 50 is assembled to the housing 20, the base 53 is positioned in the housing 20, and the multiple fins 52 are exposed to the outside of the housing 20 from the opening 25. A heat generated from the semiconductor 33 is dissipated to the outside from the heat sink fin 50 via the adhesive layer 60, or is dissipated to the outside from the housing 20 via the adhesive layer 60 and the heat sink fin 50.

The sealing member 70 is provided between the first fitting portion 51 and the second fitting portion 233. In other words, the sealing member 70 is provided between the protrusion and the recess. The sealing member 70 fills the gap between the housing 20 and the heat sink fin 50, and seals the housing 20. The sealing member 70 is, for example, a silicone resin, an epoxy resin, or a metal. When the sealing member 70 is a silicone resin or an epoxy resin, an airtightness of the housing 20 is improved, and a heat resistance of a heat dissipation path from the heat sink fin 50 to the housing 20 is improved. Alternatively, when the sealing member 70 is a metal such as solder or brazing material, the thermal resistance of the heat dissipation path from the semiconductor 33 to the housing 20 via the heat sink fin 50 is reduced. In other words, the heat dissipating performance of the heat dissipation path from the semiconductor 33 to the housing 20 via the heat sink fin 50 is improved.

The sealing member 70 has a thickness X2 and an elastic modulus Y2. The thickness X1 of the adhesive layer 60 is smaller than the thickness X2, and the elastic modulus Y1 of the adhesive layer 60 is larger than the elastic modulus Y2. As a result, the sealing member 70 is more likely to be deformed than the adhesive layer 60. When a thermal stress occurs under a thermal cycling condition due to a difference in thermal expansion coefficients among the heat sink fin 50, the semiconductor 33, the substrate 31, and the housing 20, the sealing member 70 undergoes greater deformation and absorbs more of the thermal stress than the adhesive layer 60. Therefore, the thermal stress applied to the adhesive layer 60 can be reduced.

### 1-2. Functions of the First Fitting Portion and the Second Fitting Portion

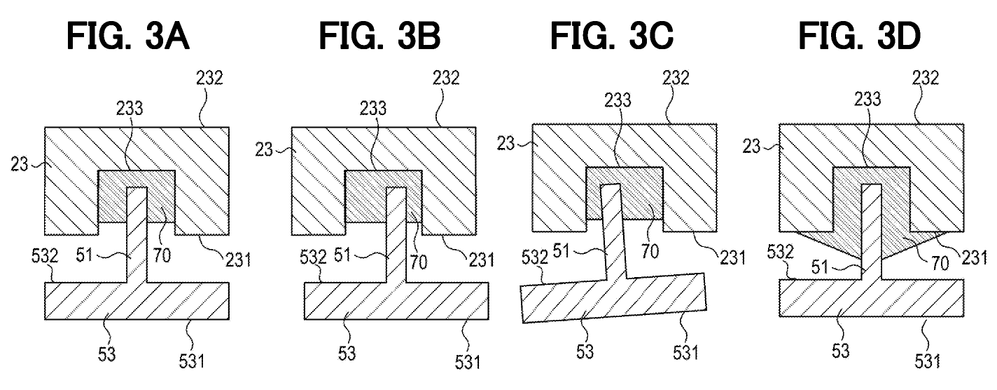

Since a gap (hereinafter referred to as first gap) is created between the surface of the first fitting portion 51 and the surface of the second fitting portion 233, assembly tolerances among the heat sink fin 50, the semiconductor 33, the substrate 31, and the housing 20 can be absorbed by the gap, thereby maintaining fitting of the heat sink fin 50 and the housing 20. Furthermore, a distance between the semiconductor 33 and the heat sink fin 50 can be maintained uniform, and a fitting of the heat sink fin 50 and the housing 20 can be maintained. FIG. 3A illustrates a state where the heat sink fin 50, the semiconductor 33, and the substrate 31 are assembled to the housing 20 at their reference positions with almost no assembly tolerance. FIG. 3B illustrates a state where at least one of the heat sink fin 50, the semiconductor 33, and the substrate 31 is assembled to the housing 20 at a position deviated in a horizontal direction from a reference position. Even in this case, the first gap absorbs the deviation in the horizontal direction.

In addition to the first gap, a gap (hereinafter, referred to as second gap) between the second face 532 and the inner surface 231 can absorb different assembly tolerances. FIG. 3C illustrates a state where at least one of the heat sink fin 50, the semiconductor 33, and the substrate 31 is assembled to the housing 20 at a position that is inclined from a reference position and deviated in the vertical direction. Even in this case, the first gap and the second gap absorb the deviation in the vertical direction and in the horizontal direction. As illustrated in FIG. 3D, even if the sealing member 70 is overflowed from the first gap, the excess sealing member 70 is absorbed by the second gap so that a distance between the semiconductor 33 and the heat sink fin 50 is maintained uniform.

### 1-3. Assembly Method

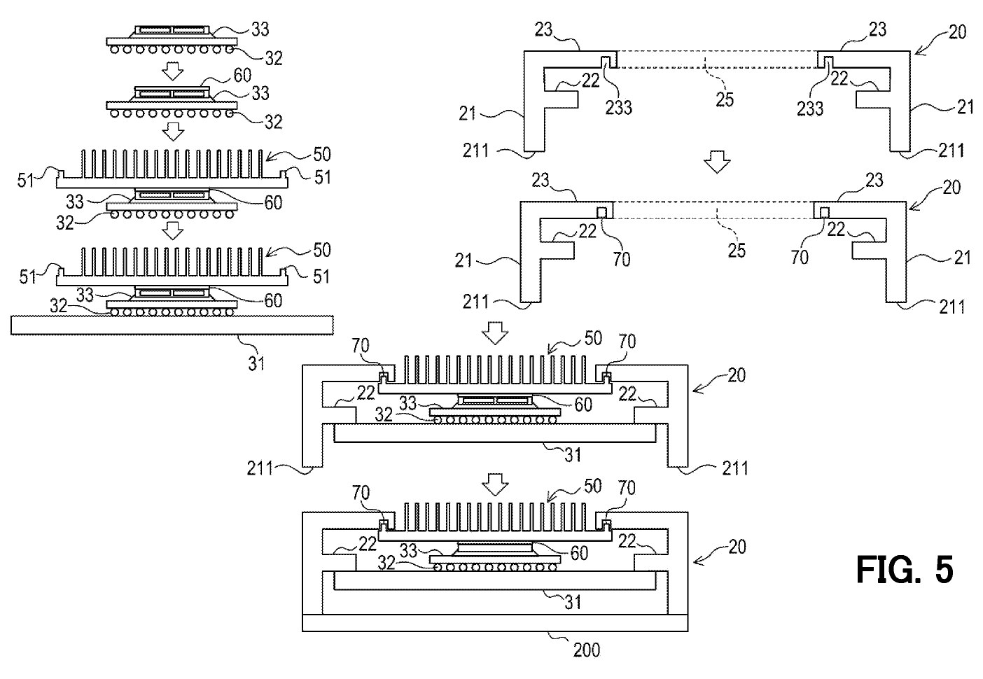

A method for assembling the electronic device 10 will be described with reference to FIG. 5. First, the adhesive layer 60 is deposited thinly and evenly on the upper surface of the semiconductor 33. Next, the base 53 of the heat sink fin 50 is placed on the adhesive layer 60, the upper surface of the semiconductor 33 and the heat sink fin 50 are pressed and heated so as to harden the adhesive layer 60, and the semiconductor 33, the adhesive layer 60, and the heat sink fin 50 are integrated. Next, the semiconductor 33 to which the heat sink fin 50 is bonded is mounted on the substrate 31. On the other hand, the sealing member 70 is injected into the second fitting portion 233 of the housing 20.

Additionally, the substrate 31 on which the semiconductor 33 is mounted is inserted through the bottom of the housing 20, and the substrate 31 is fixed to the middle face 22 with a screw. Next, the first fitting portion 51 is fitted to the second fitting portion 233 such that the surface of the first fitting portion 51 is spaced apart from the surface of the second fitting portion 233, and the multiple fins 52 of the heat sink fin 50 are exposed to the outside from the opening 25 of the housing 20. Finally, the lid 200 is attached to the lower ends 211 of the four side faces 21 of the housing 20 and seals the bottom of the housing 20.

### 1-4. Effects

According to the first embodiment described in detail above, the following effects can be obtained.

(1) The substrate 31 and the heat sink fin 50 on which the semiconductor 33 is mounted is assembled to the housing 20 without a retainer member pressing the semiconductor 33 to the heat sink fin 50. Thus, the semiconductor 33, the heat sink fin 50, and the substrate 31 can be prevented from being bent, and a space between the semiconductor 33 and the heat sink fin 50 can be thin and uniform. Additionally, the electronic device 10 can become compact and lightweight by having no retainer member. Furthermore, the first gap can absorb assembly tolerances among the heat sink fin 50, the semiconductor 33, the substrate 31, and the housing 20, thereby maintaining a distance between the semiconductor 33 and the heat sink fin 50 thin and uniform. Therefore, the heat generated from the semiconductor 33 can be effectively dissipated, and the electronic device 10 can become compact and lightweight.

(2) Since the base 53 is larger than the opening 25, the multiple fins 52 can be exposed to the outside from the opening 25 while the base 53 and the housing 20 are fitted to each other.

(3) Since the housing 20 and the heat sink fin 50 are made of the same metal material, the thermal stress generated due to a difference in the thermal expansion coefficients between the housing 20 and the heat sink fin 50 can be reduced under a thermal cycling condition. As a result, thermal fatigue life of the housing 20 and the heat sink fin 50 can be extended under the thermal cycling condition.

(4) Since the first fitting portion 51 is formed integrally with the heat sink fin 50, the number of components can be reduced, thereby reducing costs.

(5) Since the second fitting portion 233 is formed integrally with the housing 20, the number of components can be reduced, thereby reducing costs.

(6) When the adhesive layer 60 is made of a silicone resin, a heat dissipation path having high heat resistance can be realized. When the adhesive layer 60 is made of a silicone resin or an epoxy resin containing fillers having high thermal conductivity, the heat dissipating performance of the heat dissipation path can be further improved.

(7) Since the sealing member 70 are positioned between the first fitting portion 51 and the second fitting portion 233, the first gap can absorb the assembly tolerances among the heat sink fin 50, the semiconductor 33, the substrate 31, and the housing 20, and the airtightness of the housing 20 can be secured.

(8) When the sealing member 70 is a silicone resin or an epoxy resin, the airtightness of the housing 20 can be improved, and the heat resistance of the heat dissipation path from the heat sink fin 50 to the housing 20 can be improved.

(9) When the sealing member 70 is made of a metal or a brazing material, the thermal resistance of the heat dissipation path from the semiconductor 33 through the heat sink fin 50 to the housing 20 can be reduced, so that the heat generated from the semiconductor 33 can be dissipated more efficiently.

(10) The thickness X1 of the adhesive layer 60 is smaller than the thickness X2 of the sealing member 70, and the elastic modulus Y1 of the adhesive layer 60 is greater than the elastic modulus Y2 of the sealing member 70. As a result, when a thermal stress occurs due to a difference in the thermal expansion coefficients among the heat sink fin 50, the semiconductor 33, the substrate 31, and the housing 20 under the thermal cycle condition, the sealing member 70 undergoes greater deformation and absorbs more of the thermal stress than the adhesive layer 60, thereby reducing the thermal stress applied to the adhesive layer 60. As a result, the thermal cycle fatigue life of the adhesive layer 60 can be secured, and a heat dissipation path with an excellent heat dissipating performance from the semiconductor 33 to the heat sink fin 50 can be maintained.

(11) The second fitting portion 233 is provided on the inner surface 231 of the housing 20, and the first fitting portion 51 is provided on the second face 532 of the base 53. As a result, even when the base 53 and the substrate 31 on which the semiconductor 33 is mounted are larger than the opening 25 of the housing 20, the heat sink fin 50 and the substrate 31 can be inserted through the bottom of the housing 20 and assembled easily to the substrate 31.

(12) The heat sink fin 50 is attached to the semiconductor 33, the semiconductor 33 with the heat sink fin 50 is mounted on the substrate 31, the substrate 31 is inserted into the housing 20, and then the first fitting portion 51 is fitted to the second fitting portion 233. According to this process, the electronic device 10 can be assembled.

### Second Embodiment

### 2-1. Differences from First Embodiment

Since a basic configuration of a second embodiment is similar to the first embodiment, differences will be described below. The same reference numerals as those in the first embodiment indicate the same configurations, and refer to the preceding descriptions.

A configuration of an electronic device 10 according to the second embodiment is similar to the configuration of the electronic device 10 according to the first embodiment, but an assembly method is different. The assembly method of the electronic device 10 according to the second embodiment will be described below.

### 2-2. Assembly Method

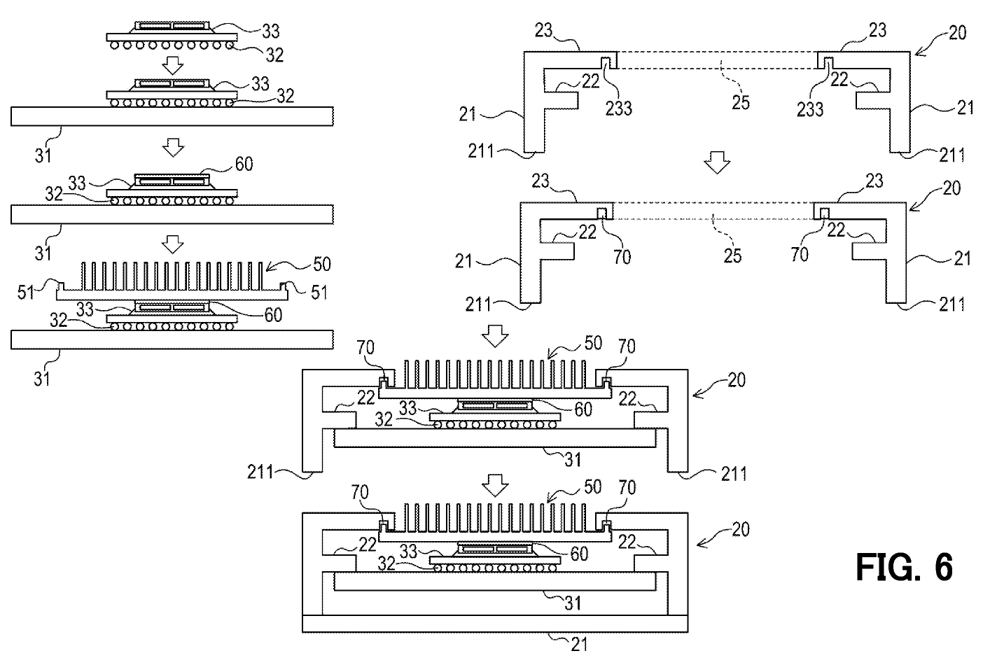

With reference to FIG. 6, a method of assembling the electronic device 10 will be described. First, the semiconductor 33 is mounted on the substrate 31. Next, the adhesive layer 60 is deposited thinly and evenly on the upper surface of the semiconductor 33 mounted on the substrate 31. Next, the base 53 of the heat sink fin 50 is placed on the adhesive layer 60, and the upper surface of the semiconductor 33 and the heat sink fin 50 are pressurized and heated to harden the adhesive layer 60, thereby integrating the semiconductor 33, the adhesive layer 60, and the heat sink fin 50. Meanwhile, the sealing member 70 is injected into the second fitting portion 233 of the housing 20.

Then, the substrate 31 on which the semiconductor 33 is mounted is inserted from the bottom of the housing 20, and the substrate 31 is fixed to the middle face 22 with a screw. Additionally, the first fitting portion 51 is fitted to the second fitting portion 233 so that the surface of the first fitting portion 51 is spaced apart from the surface of the second fitting portion 233, and the multiple fins 52 of the heat sink fin 50 are exposed to the outside from the opening 25 of the housing 20. Finally, the lid 200 is attached to the lower ends 211 of the four side faces 21 of the housing 20 and seals the bottom of the housing 20.

### 2-3. Effects

According to the second embodiment described in detail, the effects (1) to (12) of the above-described first embodiment are obtained, and further, the following effects can be obtained.

(13) The semiconductor 33 is mounted on the substrate 31, the heat sink fin 50 is attached to the semiconductor 33, the substrate 31 is inserted into the housing 20, and the first fitting portion 51 is fitted to the second fitting portion 233. According to this process, the electronic device 10 can be assembled.

### 3. Other Embodiments

Although the embodiments of the present disclosure have been described above, the present disclosure is not limited to the embodiments described above, and various modifications can be made to implement the present disclosure.

Multiple functions of one element in the above embodiment may be implemented by multiple elements, or one function of one element may be implemented by multiple elements. Further, multiple functions of multiple elements may be implemented by one element, or one function implemented by multiple elements may be implemented by one element. A part of the configuration of the above embodiment may be omitted. At least a part of the configuration of the above embodiments may be added to or replaced with another configuration of the above embodiments.

What is claimed is:

1. An electronic device, comprising:
a housing having an opening;
a substrate arranged in the housing;
a semiconductor mounted on the substrate and arranged in the housing;
a heat sink fin arranged above the semiconductor in the housing and having a part exposed to an outside of the housing from the opening;
a protrusion provided on either one of the heat sink fin or the housing; and
a recess provided on another of the heat sink fin and the housing at a position corresponding to the protrusion, wherein
the protrusion is fitted to the recess such that a surface of the protrusion is spaced away from a surface of the recess.

2. The electronic device according to claim 1, wherein
the heat sink fin includes a base positioned in the housing, and multiple fins which are connected to the base and are exposed to the outside from the opening, and
the base is larger than the opening.

3. The electronic device according to claim 1, wherein
the housing and the heat sink fin are made of a same metal material.

4. The electronic device according to claim 1, wherein
the protrusion is integrally formed with the one of the heat sink fin and the housing.

5. The electronic device according to claim 1, wherein
the recess is integrally formed with the other of the heat sink fin and the housing.

6. The electronic device according to claim 1, further comprising
an adhesive layer between the semiconductor and the heat sink fin.

7. The electronic device according to claim 1, further comprising
a sealing member between the protrusion and the recess.

8. The electronic device according to claim 6, wherein
the adhesive layer is made of a silicone resin or an epoxy resin.

9. The electronic device according to claim 7, wherein
the sealing member is made of a silicone resin or an epoxy resin.

10. The electronic device according to claim 7, wherein
the sealing member is made of a metal.

11. The electronic device according to claim 6, further comprising
a sealing member between the protrusion and the recess, wherein
a thickness of the adhesive layer is smaller than a thickness of the sealing member, and
an elastic modulus of the adhesive layer is larger than an elastic modulus of the sealing member.

12. The electronic device according to claim 2, wherein
the opening is provided on an upper face of the housing,
the upper face includes an inner surface facing an inside of the housing and an outer surface opposite the inner surface,
the base includes a first face facing the semiconductor and a second face opposite the first face,
either one of the protrusion or the recess is positioned on the inner surface, and
another of the protrusion and the recess is positioned on the second face.

13. A method for assembling the electronic device, the method comprising:
attaching a heat sink fin to a semiconductor;
mounting the semiconductor, to which the heat sink fin is attached, on a substrate;
placing the substrate, on which the semiconductor is mounted, inside a housing by inserting the substrate into the housing;
exposing a part of the heat sink fin to an outside of the housing from an opening of the housing; and
(i) fitting a protrusion of the heat sink fin to a recess of the housing such that a surface of the protrusion is spaced apart from a surface of the recess, or
(ii) fitting a recess of the heat sink fin to a protrusion of the housing such that a surface of the recess is spaced apart from a surface of the protrusion.

14. A method for assembling the electronic device, the method comprising:
mounting a semiconductor to a substrate;
attaching a heat sink fin to the semiconductor mounted on the substrate;
placing the substrate, on which the semiconductor is mounted, inside a housing by inserting the substrate into the housing;
exposing a part of the heat sink fin to an outside of the housing from an opening of the housing; and
(i) fitting a protrusion of the heat sink fin to the recess of the housing such that a surface of the protrusion is spaced apart from a surface of the recess, or
(ii) fitting a recess of the heat sink fin to a protrusion of the housing such that a surface of the recess is spaced apart from a surface of the protrusion.
